(19) United States
(12) Patent Application Publication
(10) Pub. No.: US 2012/0033699 A1
(43) Pub. Date: Feb. 9, 2012

(54) SURFACE-EMITTING LASER, SURFACE-EMITTING LASER ARRAY, DISPLAY APPARATUS INCLUDING THE SURFACE-EMITTING LASER ARRAY AS A LIGHT SOURCE, PRINTER HEAD, AND PRINTER

(75) Inventor: Yoshinobu Sekiguchi, Machida-shi (JP)

(73) Assignee: CANON KABUSHIKI KAISHA, Tokyo (JP)

(21) Appl. No.: 13/191,040

(22) Filed: Jul. 26, 2011

(30) Foreign Application Priority Data
Aug. 6, 2010 (JP) 2010-177052

(51) Int. Cl. H01S 5/18; H01S 5/34

(52) U.S. Cl. 372/45.012; 372/45.01

(57) ABSTRACT

Provided is a surface-emitting laser including a periodic gain structure, which is capable of improving uniformity of carrier injection into multiple active regions and carrier confinement, to thereby improve laser characteristics. The surface-emitting laser includes: a first DBR layer; a first cladding layer; multiple active regions each including a multiple quantum well structure; an interbarrier layer disposed between the multiple active regions; a second cladding layer; a current confinement structure; and a second DBR layer. The multiple active regions are disposed at multiple positions at which light intensity of a gain region is maximum, and the interbarrier layer has an energy level at a bottom of a conduction band thereof which is higher than an energy level at a bottom of a conduction band of a barrier layer of the multiple quantum well structure of each of the multiple active regions, which are disposed at the multiple positions.

### BACKGROUND OF THE INVENTION

1. Field of the Invention

The present invention relates to a surface-emitting laser, a surface-emitting laser array, a display apparatus including the surface-emitting laser array as a light source, a printer head, and a printer.

In particular, the present invention relates to a red surface-emitting laser with an emission wavelength near 680 nm, which has small characteristic fluctuations with respect to change in ambient temperature and has excellent temperature characteristics. Further, the present invention relates to a technology suitable for a surface-emitting laser array including the surface-emitting lasers, a display apparatus and a printer head including the surface-emitting laser array as a light source, a printer on which the printer head is mounted, and the like.

2. Description of the Related Art

In a vertical cavity surface-emitting laser (hereinafter, abbreviated to VCSEL), a current confinement portion is formed in the vicinity of an active layer through oxidation from a periphery of a mesa structure. This current confinement portion can narrow a diameter of an emission region to about several micrometers by concentrating currents in a region smaller than the mesa structure. With this, a fundamental transverse mode laser oscillation can be obtained.

However, when the diameter of the emission region is narrowed to about several micrometers by the current confinement portion, the volume of an active region is reduced, and hence the light power is reduced.

From this purpose, there has been proposed a method of increasing the volume of the active layer by providing a periodic gain structure in which multiple active regions are disposed correspondingly to multiple maximum portions of the light intensity distribution of the active region sandwiched between two DBR mirrors, to thereby increase the light power.

Specifically, Japanese Patent Application Laid-Open No. 2001-94209 proposes a periodic gain structure in which the active regions are disposed correspondingly to three maximum portions of the light intensity distribution of the active region sandwiched between the two DBR mirrors.

In the technology described in Japanese Patent Application Laid-Open No. 2001-94209, carriers are laterally-injected into the multiple active layers, which enables uniform injection of carriers into the multiple active layers.

In a conventional VCSEL including a periodic gain structure, in which carriers are vertically-injected, multiple active regions are disposed correspondingly to the light intensity distribution, and the multiple active regions are spaced apart from one another.

When the injected carriers are concentrated in a certain active region on the P-side, carriers cannot be sufficiently provided in an active region on the N-side.

Further, multiple active regions are provided between the two cladding layers for carrier confinement, and hence the function of confining carriers in each of the active regions becomes insufficient, which leads to deterioration in temperature characteristics.

### SUMMARY OF THE INVENTION

The present invention has been made in view of the above-mentioned problems, and therefore has an object to provide a surface-emitting laser including a periodic gain structure, which is capable of improving uniformity of carrier injection into multiple active regions and carrier confinement, to thereby improve laser characteristics.

Further, the present invention has an object to provide a surface-emitting laser array including the above-mentioned surface-emitting lasers, a display apparatus and a printer head including the surface-emitting laser array as a light source, and a printer.

A surface-emitting laser according to the present invention comprises: a first DBR layer; a first cladding layer formed on the first DBR layer; multiple active regions formed on the first cladding layer, the multiple active regions each including a multiple quantum well structure; an interbarrier layer disposed between the multiple active regions; a second cladding layer formed on the multiple active regions; a current confinement structure formed on the second cladding layer; and a second DBR layer formed on the current confinement structure, wherein: the multiple active regions are disposed at multiple positions at which light intensity of a gain region is maximum; and the interbarrier layer has an energy level at a bottom of a conduction band thereof which is higher than an energy level at a bottom of a conduction band of a barrier layer of the multiple quantum well structure of each of the multiple active regions, which are disposed at the multiple positions.

According to the present invention, it is possible to achieve the surface-emitting laser including the periodic gain structure, which is capable of improving uniformity of carrier injection into multiple active regions and carrier confinement, to thereby improve laser characteristics.

Further, it is possible to provide the surface-emitting laser array including the above-mentioned surface-emitting lasers, the display apparatus and the printer head including the surface-emitting laser array as a light source, and the printer.

Further features of the present invention will become apparent from the following description of exemplary embodiments with reference to the attached drawings.

### BRIEF DESCRIPTION OF THE DRAWINGS

FIG. 1 is a schematic diagram illustrating conduction band energy and light intensity near a periodic gain active region, for describing an embodiment of the present invention.

FIG. 2 is a schematic view illustrating a configuration of a VCSEL according to the embodiment of the present invention.

FIG. 3 is a graph illustrating current-light power characteristics of the VCSEL according to the embodiment of the present invention.

FIG. 4 is a graph illustrating current-light power characteristics of a VCSEL in another configuration according to an embodiment formed for improving temperature characteristics in the above-mentioned embodiment of the present invention of FIG. 3.

FIG. 5 is a graph illustrating current-light power characteristics of a VCSEL in further another configuration according to an embodiment formed for preventing characteristic deterioration in the above-mentioned embodiment of the present invention of FIG. 4.

FIG. 6A is a view illustrating a step of a method of manufacturing a VCSEL according to an example of the present invention.

FIG. 6B is a view illustrating a step of the method of manufacturing the VCSEL according to the example of the present invention.

FIG. 6C is a view illustrating a step of the method of manufacturing the VCSEL according to the example of the present invention.

FIG. 6D is a view illustrating a step of the method of manufacturing the VCSEL according to the example of the present invention.

FIG. 7 is a diagram illustrating conduction band energy near a periodic gain active region of a VCSEL according to a comparative example.

FIG. 8 is a graph illustrating current-light power characteristics of the VCSEL according to the comparative example.

### DESCRIPTION OF THE EMBODIMENTS

Next, a surface-emitting laser according to an embodiment of the present invention is described.

In this embodiment, an energy level at a bottom of a conduction band of an interbarrier layer is set to be higher than an energy level at a bottom of a conduction band of a barrier layer of a multiple quantum well structure of an active region.

With this, carriers are distributed to multiple active regions, and further carrier confinement in each of the active regions is improved. In this manner, the characteristics of the surface-emitting laser are improved.

Further, a bandgap of the interbarrier layer is set larger than a bandgap of the barrier layer in each of the active regions. With this, the energy at the bottom of the conduction band of the interbarrier layer becomes higher than the energy at the bottom of the conduction band of the barrier layer, and hence a similar effect can be obtained.

Note that, in this configuration, widening the bandgap of the interbarrier layer provides an excessive effect of blocking the holes, which deteriorates the laser characteristics.

For this purpose, in embodiment of the present invention, the interbarrier layer is doped with P-type impurities, to thereby lower the effect of blocking the holes and prevent deterioration in laser characteristics.

Further, the energy level at the bottom of the conduction band of the interbarrier layer is set lower than an energy level at a bottom of a conduction band of a P-side cladding layer. With this, carriers are distributed to each of the active regions, and further the overflow of the carriers may be prevented.

In an AlGaInP based material which nearly lattice matches to GaAs, the energy of the bottom of the conduction band at Γ point increases along with the increase of an Al composition, is maximum when the Al composition is near 0.32 (Al_{0.32}Ga_{0.18}InP), and then decreases.

Therefore, when the Al composition is near 0.32 (Al_{0.32}Ga_{0.18}InP), the effect of blocking the electron carriers by the P-side cladding layer is provided at maximum, and also the overflow of the carriers can be suppressed at maximum.

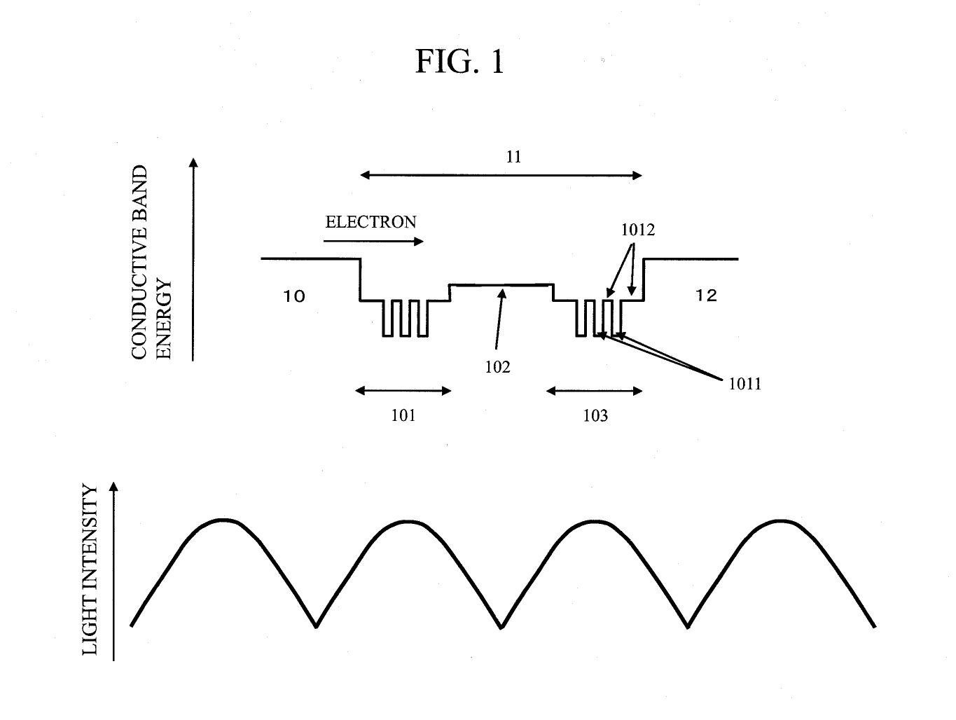

FIG. 1 is a diagram illustrating the conduction band energy near the active layer in the configuration above, which shows the principle of the present invention.

Two active regions 101 and 103, which constitute the periodic gain structure, each include a multiple quantum well structure, and an interbarrier layer 102 is positioned between the two active regions 101 and 103.

Further, as illustrated in FIG. 1, the two active regions 101 and 103 are disposed at different peak positions of the light intensity, at which the light intensity of the gain region is maximum. Note that, “maximum” refers not only to the maximum value in a strict sense, but also to a value near the maximum value within a range capable of providing the effect of this embodiment.

The interbarrier layer 102 has an energy level at the bottom of the conduction band thereof which is higher than an energy level at a bottom of a conduction band of a barrier layer of the multiple quantum well structure.

By distributing a part of the carriers injected from the N-side to the N-side active region 101, carrier concentration in the P-side active region 103 is prevented.

In addition, because the energy at the bottom of the conduction band of the interbarrier layer is higher than the energy at the bottom of the conduction band of the barrier layer of each of the active regions, the distributed carriers are confined in the active regions 101 and 103.

As described above, by distributing the carriers to the multiple active regions and confining the carriers in each of the active regions, the carriers are prevented from being concentrated in the P-side active region and occurrence of overflow of the carriers is prevented.

In addition, by confining the carriers in each of the active regions, the temperature characteristics can be improved.

With the improvement of the temperature characteristics of the surface-emitting laser described above, a significant effect can be obtained in the periodic gain structure in which sufficient difference in conduction band energy cannot be ensured in the energy band structure of the active region due to the limitation of semiconductor materials.

Particularly in a red surface-emitting laser in which an active region is formed of an AlGaInP based material, the laser characteristics may be improved.

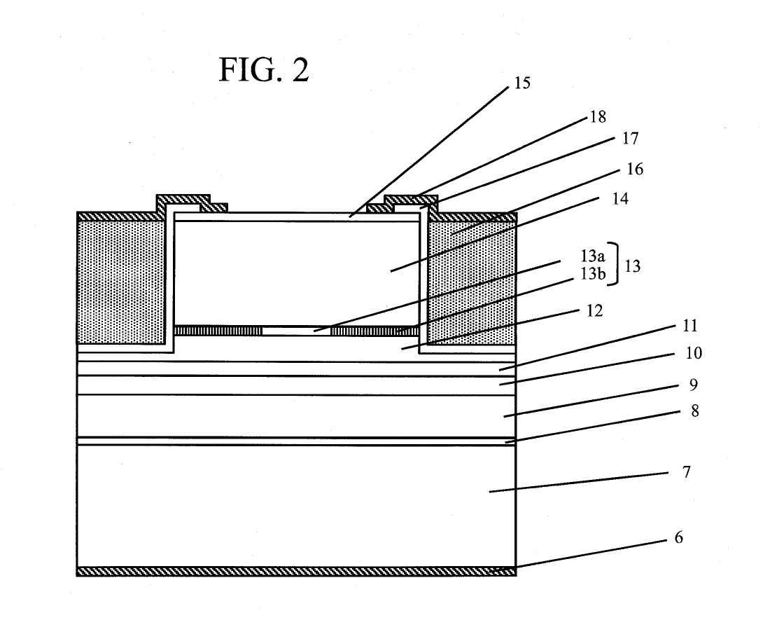

Hereinafter, the surface-emitting laser according to this embodiment is described with reference to FIG. 2.

FIG. 2 illustrates a schematic configuration of the surface-emitting laser according to the present invention.

The surface-emitting laser includes an n-type electrode 6, a GaAs substrate 7, an n-type GaAs buffer layer 8, an n-type DBR layer 9 (first DBR layer), an n-type cladding layer 10 (first cladding layer), a periodic gain active region 11 (active region), and a p-type cladding layer 12 (second cladding layer).

Further, the surface-emitting laser includes a non-oxidizing region 13a and a periphery-oxidizing region 13b which constitute a current confinement portion 13, a p-type DBR layer 14 (second DBR layer), a p-type contact layer 15, a buried insulating layer 16, an insulating layer 17, and a p-type electrode 18.

FIG. 1 is an energy band diagram with the periodic gain active region 11 enlarged.

The periodic gain active region 11 includes the two N-side and P-side active regions 101 and 103, and the interbarrier layer 102 disposed between the two active regions.

Each of the active regions includes a multiple quantum well structure, and an energy level at a bottom of a conduction band of the interbarrier layer is higher than an energy level of a barrier layer of the multiple quantum well structure.

As illustrated in FIG. 1, the interbarrier layer 102 distributes a part of the electron carriers injected from the N-side to the N-side active region 101, to thereby prevent carrier concentration in the P-side active region 103.

In addition, because the energy at the bottom of the conduction band of the interbarrier layer is higher than the energy of the barrier layer of each of the active regions, the distributed carriers are confined in each of the active regions 101 and 103.

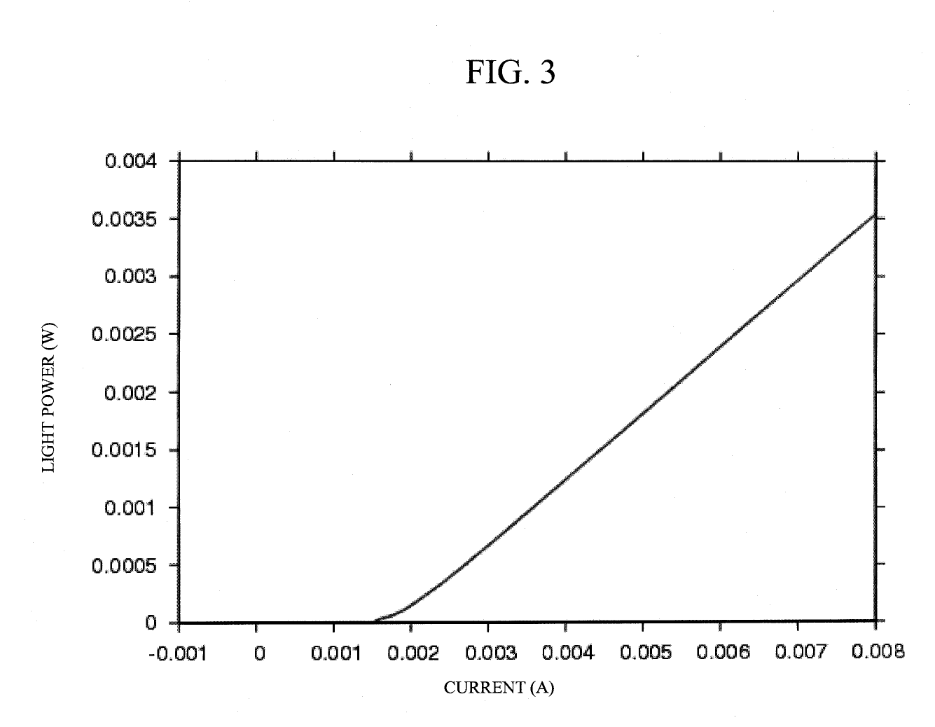

FIG. 3 illustrates current-light power characteristics of the red surface-emitting laser with a red emission wavelength, in which the periodic gain active region is made of an AlGaInP based material.

In order to set the relation of the energy of the conduction band in the periodic gain active region as the band diagram of FIG. 1, the n-type cladding layer 10 is made of Al_{0.32}Ga_{0.18}In_{0.5}P, the quantum well layer 1011 of the active region is made of Ga_{0.38}In_{0.52}P, and the barrier layer 1012 is made of Al_{0.15}Ga_{0.35}In_{0.5}P. Further, the interbarrier layer 102 is made of Al_{0.25}Ga_{0.25}In_{0.5}P, and the p-type cladding layer 12 is made of Al_{0.32}Ga_{0.18}In_{0.5}P.

In this case, the threshold current is 1.6 mA, and the light power at 8 mA is 3.5 mW.

Note that, the present invention is not limited to the above-mentioned configuration, and the barrier layer, the interbarrier layer, and the p-type cladding layer may be made of AlₓGa₁₋ₓIn_{0.5}P, in which an Al composition x of the barrier layer is 0.25 or lower, the Al composition x of the interbarrier layer is 0.32 or lower, and the Al composition x of the p-type cladding layer is 0.32 or higher.

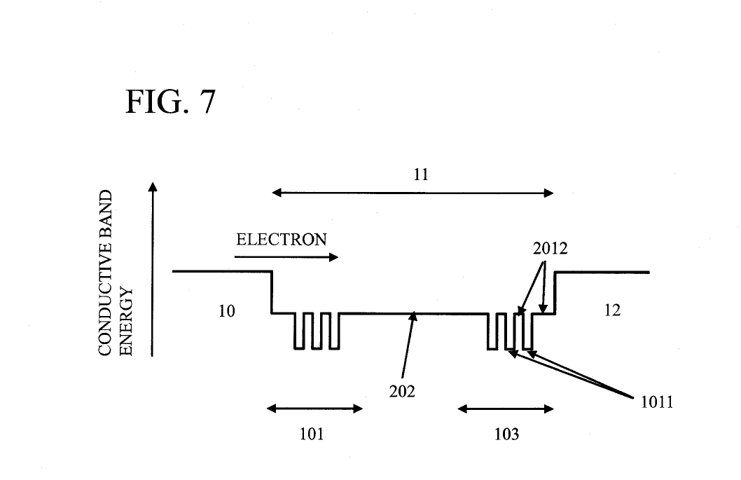

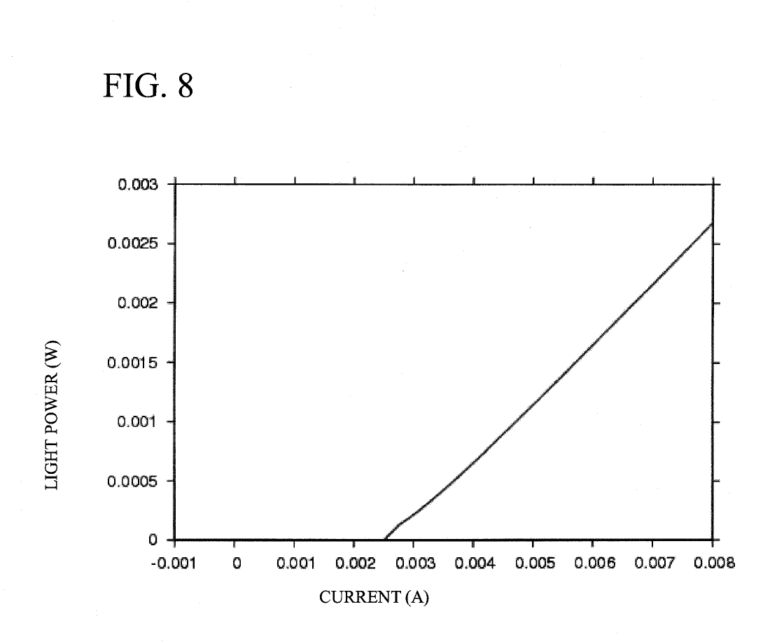

FIGS. 7 and 8 illustrate a comparative example of the present invention.

FIG. 7 illustrates the relation of the energy of the conduction band in the periodic gain active region. In this comparative example, unlike the embodiment of the present invention, the barrier layer 2012 of the active region and the interbarrier layer 202 are made of the same composition of Al_{0.25}Ga_{0.25}In_{0.5}P.

That is, the energy level at the bottom of the conduction band of the interbarrier layer 202 is the same as the energy level at the bottom of the conduction band of the barrier layer 2012 of the multiple quantum well structure.

FIG. 8 is a graph illustrating current-light power characteristics of the red surface-emitting laser, in which the periodic gain active region is formed of an AlGaInP based material, in the comparative example.

The comparative example differs in laser characteristics from the embodiment illustrated in FIG. 3 in that, compared with the embodiment, the threshold current increases from 1.6 mA to 2.5 mA, and the light power at 8 mA decreases from 3.5 mW to 2.7 mW.

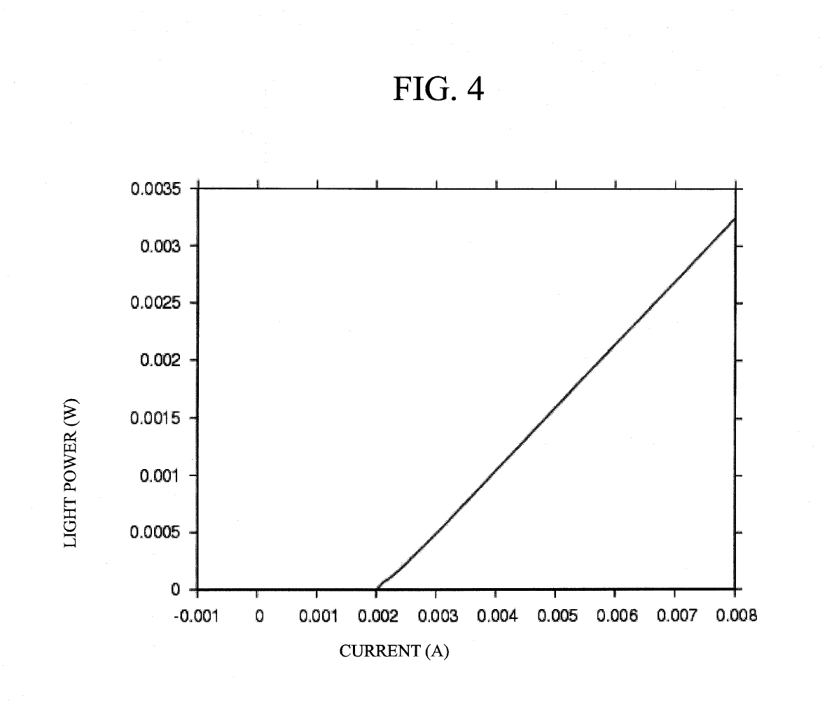

FIG. 4 is a graph illustrating current-light power characteristics of a VCSEL in another configuration according to an embodiment formed for improving temperature characteristics in the above-mentioned embodiment of the present invention of FIG. 3.

FIG. 4 illustrates the current-light power characteristics in a configuration in which, in order to improve the temperature characteristics, the Al composition of the interbarrier layer 102 is increased to Al_{0.32}Ga_{0.18}In_{0.5}P from the configuration of FIG. 3, to thereby improve the carrier confinement effect in each of the active regions. Note that, the barrier layer 1012 is made of Al_{0.15}Ga_{0.35}In_{0.5}P.

Compared with the case of FIG. 3, the threshold current is increased from 1.6 mA to 2.0 mA, and the light power at 8 mA is decreased from 3.5 mW to 3.2 mW.

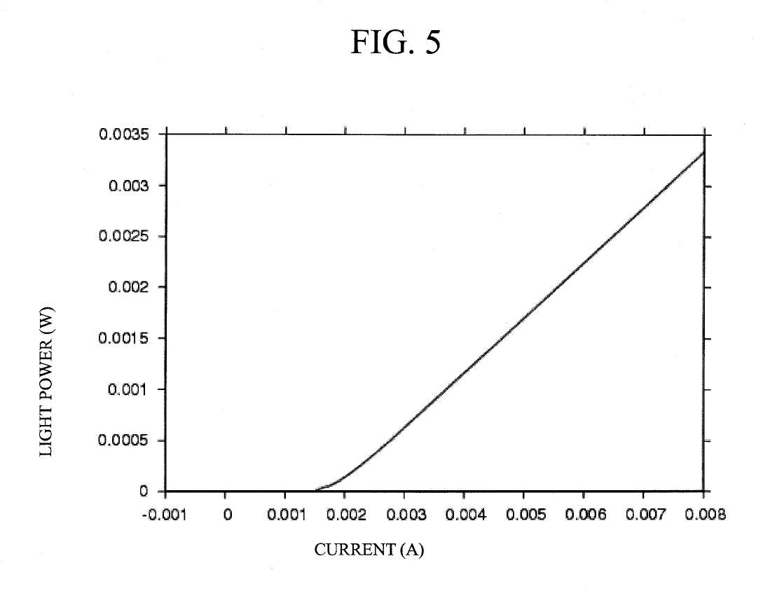

Further, FIG. 5 is a graph illustrating current-light power characteristics of a VCSEL in further another configuration according to an embodiment formed for preventing characteristic deterioration in the above-mentioned embodiment of the present invention of FIG. 4.

FIG. 5 illustrates the current-light power characteristics in a configuration in which, in order to prevent characteristic deterioration in FIG. 4, the interbarrier layer 102 made of Al_{0.32}Ga_{0.18}In_{0.5}P is p-doped at about 10¹⁷/cm³.

Compared with the case of FIG. 4, the threshold current is decreased from 2.0 mA to 1.6 mA, and the light power at 8 mA is increased from 3.2 mW to 3.3 mW.

Table 1 summarizes the results above in a list.

TABLE 1

| | | | threshold | light power |
|---|---|---|---|---|
| | inter | p | current | (mW) at |
| barrier | barrier | doping | (mA) | 8 mA |
| Al_{0.25}Ga_{0.25}InP | Al_{0.25}Ga_{0.25}InP | Φ | 2.5 | 2.7 |
| Al_{0.15}Ga_{0.35}InP | Al_{0.25}Ga_{0.25}InP | Φ | 1.6 | 3.5 |
| ↑ | Al_{0.30}Ga_{0.20}InP | Φ | 2 | 3.4 |
| ↑ | Al_{0.32}Ga_{0.18}InP | Φ | 2 | 3.2 |
| Al_{0.15}Ga_{0.35}InP | Al_{0.25}Ga_{0.25}InP | 1.0E+23 | 1.6 | 3.6 |
| ↑ | Al_{0.30}Ga_{0.20}InP | 1.0E+23 | 1.6 | 3.5 |
| ↑ | Al_{0.32}Ga_{0.18}InP | 1.0E+23 | 1.6 | 3.3 |

As described above, in the surface-emitting laser including the periodic gain active region according to the embodiments of the present invention, the energy at the bottom of the conduction band of the interbarrier layer disposed between the multiple active regions is set higher than the energy at the bottom of the conduction band of the barrier layer of each of the active regions.

With this, carriers are distributed to the multiple active regions, and further carrier confinement in each of the active regions is improved. In this manner, the characteristics of the surface-emitting laser are improved.

Further, it is possible to obtain a similar effect even with a configuration in which the interbarrier layer comprises a superlattice structure including at least one barrier layer which electron can tunnel and the electron tunnels the superlattice structure at an energy level which is higher than the energy level at the bottom of the conduction band of the barrier layer of the multiple quantum well structure in each of the active regions.

For example, a quantum well layer of the superlattice structure is formed to have the same composition as the barrier layer of the active region, and the barrier layer which the electron tunnels is formed to have the same composition as the cladding layer. In this manner, the energy level at which the electron tunnels can be set higher than the energy at the bottom of the conduction band of the barrier layer of the active region.

Further, it is possible to set the energy level at which the electron tunnels the superlattice structure lower than the energy level at the bottom of the conduction band of the p-type cladding layer.

In this manner, it is possible to achieve the interbarrier effect of the present invention.

Note that, the tunneling probability of the electron the barrier layer greatly depends on the thickness of the barrier layer forming the superlattice structure, and hence it is necessary that the interbarrier with the superlattice structure has a high tunneling probability, and therefore a thin barrier layer, that is, the barrier layer with a thickness of about several atomic layers is desired.

Further, by forming a superlattice structure including at least two barrier layers, with the use of the resonant tunneling effect caused between the quantum wells, it is possible to control the energy level at which the electron can tunnel and the tunneling probability.

The embodiments of the present invention are described above while employing the surface-emitting laser including the periodic gain active region made of the AlGaInP based material, but even if an AlGaAs based or InGaAs based material is used for the periodic gain active region, the similar effect can be obtained.

Further, according to the VCSEL of the embodiments of the present invention, particularly in the red surface-emitting laser including the active layer made of an AlGaInP based material, uniformity of carrier injection into the multiple active regions and carrier confinement may be improved.

Further, the laser characteristics may be improved, such as decrease in threshold current, increase in light power, and reduction in temperature dependence. Therefore, this technology is suitable for an apparatus including a surface-emitting laser array as a light source, the surface-emitting laser array including the surface-emitting lasers which are one-dimensionally or two-dimensionally arranged in array.

With this, for example, it is possible to achieve a printer on which a printer head including the surface-emitting laser array as a light source is mounted, a display apparatus including the surface-emitting laser array as a light source, and the like.

### Example

As an example, a method of manufacturing a surface-emitting laser is described.

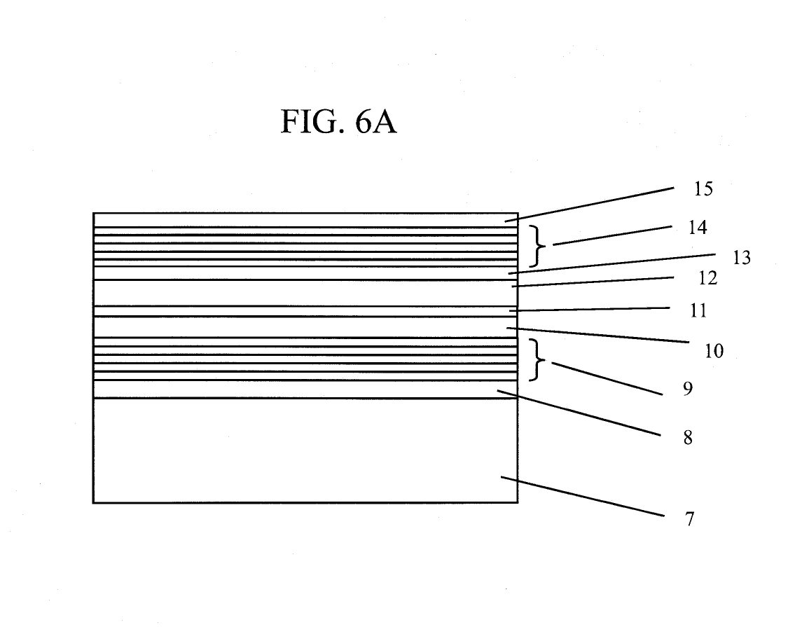

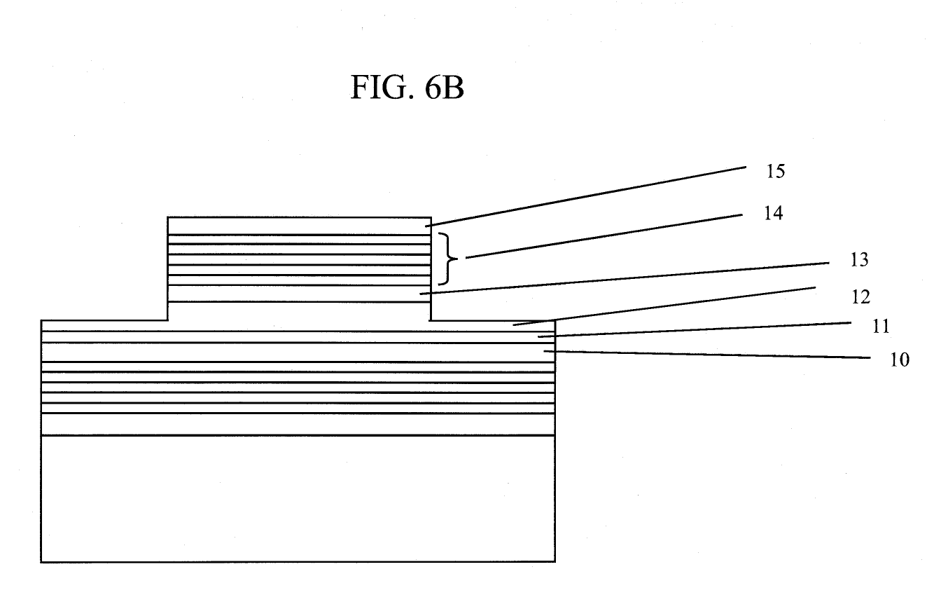

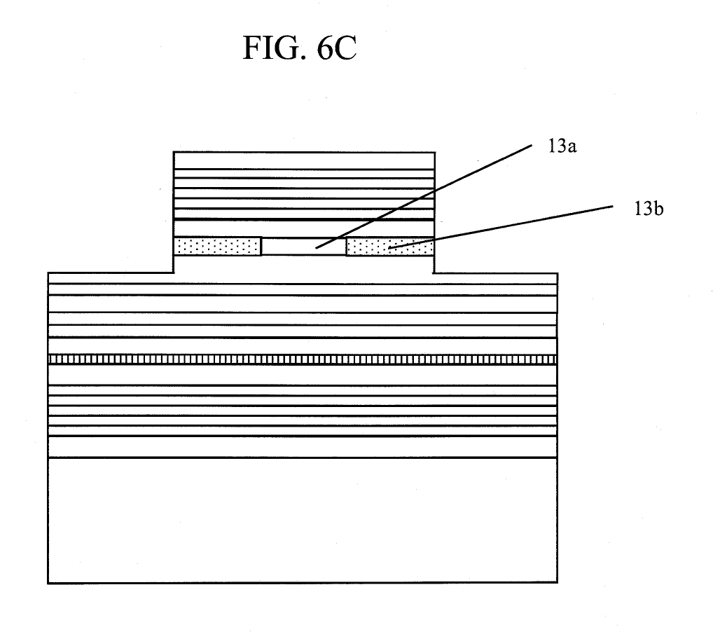

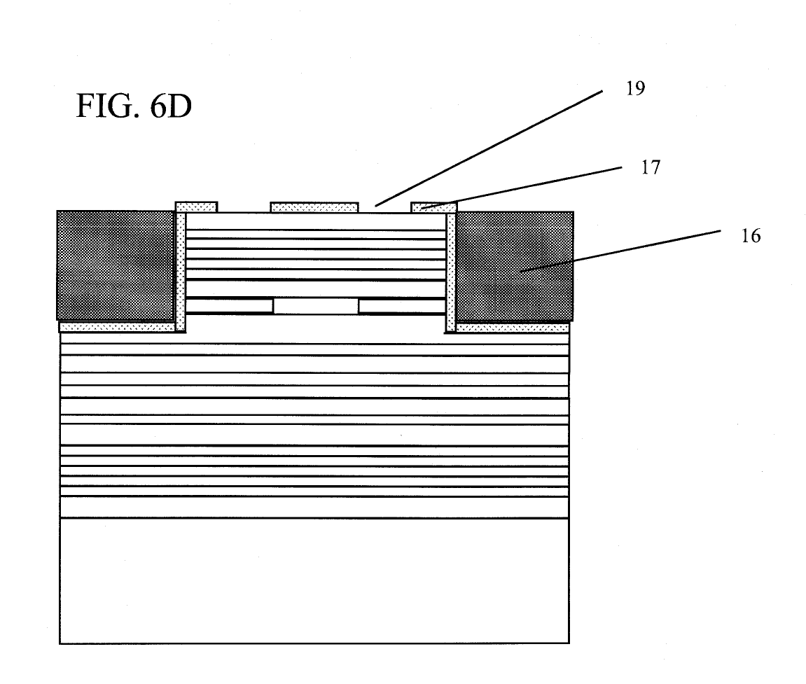

FIGS. 6A to 6D are views illustrating the manufacturing steps of the method of manufacturing a surface-emitting laser according to this example.

Note that, in FIGS. 6A to 6D, layers having the same functions as those in FIGS. 1 and 2 are denoted by the same reference symbols.

As illustrated in the layer configuration of FIG. 6A, the respective layers are sequentially grown on the GaAs substrate 7 by an MOCVD method, which is a well-known technology, as below.

That is, the n-type GaAs buffer layer 8, the n-type DBR layer 9, the n-type cladding layer 10, the periodic gain active region 11, the p-type cladding layer 12, the current confinement portion 13, the p-type DBR layer 14, and the p-type contact layer 15 are sequentially grown.

The n-type cladding layer 10 is formed of an n-type Al_{0.32}Ga_{0.18}In_{0.5}P layer. Further, the n-type DBR layer 9 is a laminate in which Al_{0.5}Ga_{0.5}As layers and AlAs layers are alternately laminated by 54 cycles such that the film thickness of each layer is λ/4nᵣ (where λ is an emission wavelength of the laser and nᵣ is a refractive index of the medium forming the layer).

The periodic gain active layer 11 includes two multiple quantum well active regions, and as illustrated in the diagram of the conduction band energy of FIG. 1, each of the multiple quantum well active regions includes the quantum well layer 1011 made of undoped GaInP and the barrier layer 1012 made of undoped Al_{0.15}Ga_{0.35}In_{0.5}P. Between the two active regions, the interbarrier layer 102 made of Al_{0.25}Ga_{0.25}In_{0.5}P is disposed, which has an energy level at the bottom of the conduction band thereof higher than that of the barrier layer made of Al_{0.15}Ga_{0.35}In_{0.5}P. The current confinement portion 13 includes the non-oxidizing region 13a and the periphery-oxidizing region 13b. The non-oxidizing region 13a is formed of an Al_{0.98}Ga_{0.02}As layer, and the periphery-oxidizing region 13b is formed by oxidizing the Al_{0.98}Ga_{0.02}As layer to cause insulation. The p-type DBR layer 14 is a laminate in which Al_{0.5}Ga_{0.5}As layers and AlAs layers are alternately laminated by 34 cycles such that the film thickness of each layer is λ/4nᵣ (where λ is an emission wavelength of the laser and nᵣ is a refractive index of the medium forming the layer).

The p-type contact layer 15 is formed of a GaAs layer with a high carrier density in order to obtain a low-resistance ohmic contact when forming the p-type metal electrode 18 (FIG. 2).

Next, as illustrated in FIG. 6B, a SiO₂ film is deposited on a top surface of the substrate. Then, after this deposition, a resist pattern is formed, and with this pattern as a mask, etching is performed until at least an Al_{0.98}Ga_{0.02}As layer which becomes the current confinement structure is exposed by a well-known etching technology, to thereby form a mesa structure having a diameter of about 30 μₘ. After that, the resist is removed.

Then, as illustrated in FIG. 6C, the above-mentioned exposed Al_{0.98}Ga_{0.02}As layer is selectively oxidized from the periphery of the mesa structure through a well-known wet oxidation. With this, the non-oxidizing region 13a formed of an Al_{0.98}Ga_{0.02}As layer and the periphery-oxidizing region 13b formed of an oxide of Al_{0.98}Ga_{0.02}As are formed, and the non-oxidizing region 13a serves as a current path to the active layer.

Note that, the opening portion diameter of the current confinement portion formed in the vicinity of the active layer of the surface-emitting device is appropriately determined depending on a necessary diameter of a current injection region.

Next, as illustrated in FIG. 6D, the SiO₂ film is removed and the SiN protective film 17 and the buried insulating layer 16 are deposited all over the surface. Then, a window 19 having an inner diameter of 10 μm and an outer diameter of 15 μm is opened in a ring shape excluding a light emitting portion, and then Ti and Au which form the p-type metal electrode 18 (FIG. 2) are successively deposited.

In addition, AuGe, Ni, and Au are successively formed on the GaAs substrate side as the n-type metal electrode 6 (FIG. 2), and thus the surface-emitting laser structure of FIG. 2 is obtained.

In the surface-emitting laser structure of FIG. 2, by applying an electric field between the p-type electrode and the n-type electrode, when the electron carriers injected from the n-type electrode reach the periodic gain active region, a part of the electron carriers are distributed to and confined in the N-side active region owing to the effect of the interbarrier layer.

The remaining electron carriers cross over the interbarrier layer to reach the P-side active region. In each of the active regions, light conversion occurs due to recombination with the holes, and with the resonance between the upper and lower DBR layers, laser oscillation is achieved.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-177052, filed Aug. 6, 2010, which is hereby incorporated by reference herein in its entirety.

What is claimed is:

1. A surface-emitting laser, comprising:
a first DBR layer;
a first cladding layer formed on the first DBR layer;
multiple active regions formed on the first cladding layer, the multiple active regions each including a multiple quantum well structure;
an interbarrier layer disposed between the multiple active regions;
a second cladding layer formed on the multiple active regions;
a current confinement structure formed on the second cladding layer; and
a second DBR layer formed on the current confinement structure, wherein:
the multiple active regions are disposed at multiple positions at which light intensity of a gain region is maximum; and
the interbarrier layer has an energy level at a bottom of a conduction band thereof which is higher than an energy level at a bottom of a conduction band of a barrier layer of the multiple quantum well structure of each of the multiple active regions, which are disposed at the multiple positions.

2. The surface-emitting laser according to claim 1, wherein:
the second cladding layer is of a p-type; and
the energy level at the bottom of the conduction band of the interbarrier layer is lower than an energy level at a bottom of a conduction band of the p-type second cladding layer.

3. The surface-emitting laser according to claim 1, wherein:
the interbarrier layer comprises a superlattice structure including at least one barrier layer which electron can tunnel; and
the electron tunnels the superlattice structure at an energy level which is higher than the energy level at the bottom of the conduction band of the barrier layer of the multiple quantum well structure.

4. The surface-emitting laser according to claim 1, wherein:
the interbarrier layer comprises a superlattice structure including at least one barrier layer which electron can tunnel;
the second cladding layer is of a p-type; and
the electron tunnels the superlattice structure at an energy level which is lower than an energy level at a bottom of a conduction band of the second cladding layer.

5. The surface-emitting laser according to claim 1, wherein:
the first DBR layer and the first cladding layer are of an n-type;
the second DBR layer and the second cladding layer are of a p-type; and
the interbarrier layer is p-doped.

6. The surface-emitting laser according to claim 1, wherein the interbarrier layer has a bandgap larger than a bandgap of the barrier layer of the multiple quantum well structure.

7. The surface-emitting laser according to claim 1, wherein:
the surface-emitting laser has a red emission wavelength; and
the multiple quantum well structure, the barrier layer, the interbarrier layer, the first cladding layer, and the second cladding layer are made of AlGaInP having different compositions.

8. The surface-emitting laser according to claim 1, wherein:
the second cladding layer is of a p-type;
the barrier layer, the interbarrier layer, and the second cladding layer are made of AlₓGa₁₋ₓIn_{0.5}P; and
the barrier layer has an Al composition x of 0.25 or lower, the interbarrier layer has the Al composition x of 0.32 or lower, and the p-type second cladding layer has the Al composition x of 0.32 or higher.

9. A surface-emitting laser array, comprising the surface-emitting lasers according to claim 1, which are one of one-dimensionally or two-dimensionally arranged in array.

10. A display apparatus, comprising the surface-emitting laser array according to claim 9 as a light source.

11. A printer, comprising a printer head including the surface-emitting laser array according to claim 9 as a light source.
